(19) United States
(12) Patent Application Publication
(10) Pub. No.: US 2007/0133331 A1
(43) Pub. Date: Jun. 14, 2007

(54) DEVICE AND METHOD FOR REDUCING REFRESH CURRENT CONSUMPTION

(75) Inventors: Duk-Ha PARK, Gyeonggi-do (KR); Kee Won KWON, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggid-do (KR)

(21) Appl. No.: 11/567,554

(22) Filed: Dec. 6, 2006

(30) Foreign Application Priority Data
Dec. 6, 2005 (KR) 2005-0117842

(51) Int. Cl. G11C 7/10

(52) U.S. Cl. 365/222; 365/189.05; 365/194

(57) ABSTRACT

I claim a device and method for reducing current consumption. The device including a memory cell array having a first region to store normal data and a second region to store both normal data and parity data associated with error correction functionality, and a refresh control unit to perform refresh operations on the memory cell array, the refresh control unit adapted to adjust a cycle associated with the performance of the refresh operations responsive to the storage of normal data in the second region.

### RELATED APPLICATIONS

This patent application claims priority from Korean Patent Application 10-2005-117842, filed on Dec. 6, 2005, which we incorporate by reference.

### BACKGROUND OF THE INVENTION

1. Field of the Invention

The present invention relates, generally, to memory devices and, more particularly, to a memory device and method for reducing refresh current consumption.

2. Description of the Related Art

In memory devices, such as a Dynamic Random Access Memory (DRAM), memory cells may degrade over time, e.g., through the degradation of a dielectric layer, the introduction of foreign particles, etc. This memory cell degradation may cause the memory cells to store data incorrectly, thus contributing to memory device failure. To help overcome memory cell degradation, memory devices may include error correction code (ECC) functionality or circuits to detect and correct errors in stored data. For instance, an ECC circuit may generate parity data according to data to be stored by the memory cells, and then store the parity data in a parity memory portion of the memory device. During data retrieval operations, the memory device may use the parity data to detect and correct errors in data retrieved from the memory cells.

FIG. 1 shows a conventional memory device including a parity memory region 10 and a normal memory region 20. The conventional memory device stores normal data NDAT in the normal memory region 20 and parity data PDAT in the parity memory region 10. That is, the memory device only stores parity data PDAT in the parity memory region 10, which maintains ECC functionality of the memory device. The parity memory region 10 typically is about half the size of the normal memory region 20. Since the conventional memory device allocates a significant portion of the memory cells to exclusively store parity data PDAT, the capacity of the memory device to store normal data NDAT is reduced.

Memory devices, such as a DRAM, also execute refresh operations to effectively preserve data stored in the memory cells. These refresh operations, however, consume a large amount or current due to the switching of transistors embedded in the memory device. Particularly, when a refresh operation is executed during each cycle in standby mode or power down mode of the memory device, the current consumption for the refresh operation accounts for a large portion of the total current consumption by the memory device.

To decrease current consumption, memory devices may control the refresh operation cycle. Since ECC functionality can correct improperly stored or preserved data, memory devices that include ECC circuits may lengthen their refresh operation cycles and thus decrease the current consumption.

### SUMMARY OF THE INVENTION

Embodiments of the present invention provide a memory device and method to reduce current consumption in the refresh operations. The device including a memory cell array having a first region to store normal data and a second region to store both normal data and parity data associated with error correction functionality, and a refresh control unit to perform refresh operations on the memory cell array, the refresh control unit adapted to adjust a cycle associated with the performance of the refresh operations responsive to the storage of normal data in the second region.

### BRIEF DESCRIPTION OF THE DRAWINGS

The features and advantages of the present invention will be more apparent with the detailed description of exemplary embodiments referencing the attached drawings.

FIG. 1 is a diagram showing a conventional memory device.

FIG. 2 is a block diagram showing a memory device useful with embodiments of the present invention.

FIG. 3 is a block diagram showing example embodiments of the memory cell array shown in FIG. 2.

FIGS. 4A-4C are block diagrams showing other example embodiments of the memory cell array shown in FIG. 2.

FIG. 5 is a flowchart example for the operation of the memory device shown in FIG. 2.

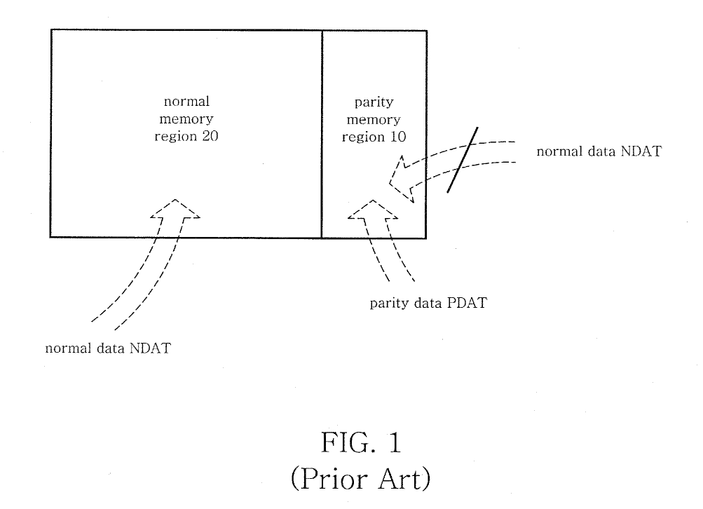

### DETAILED DESCRIPTION OF THE INVENTION

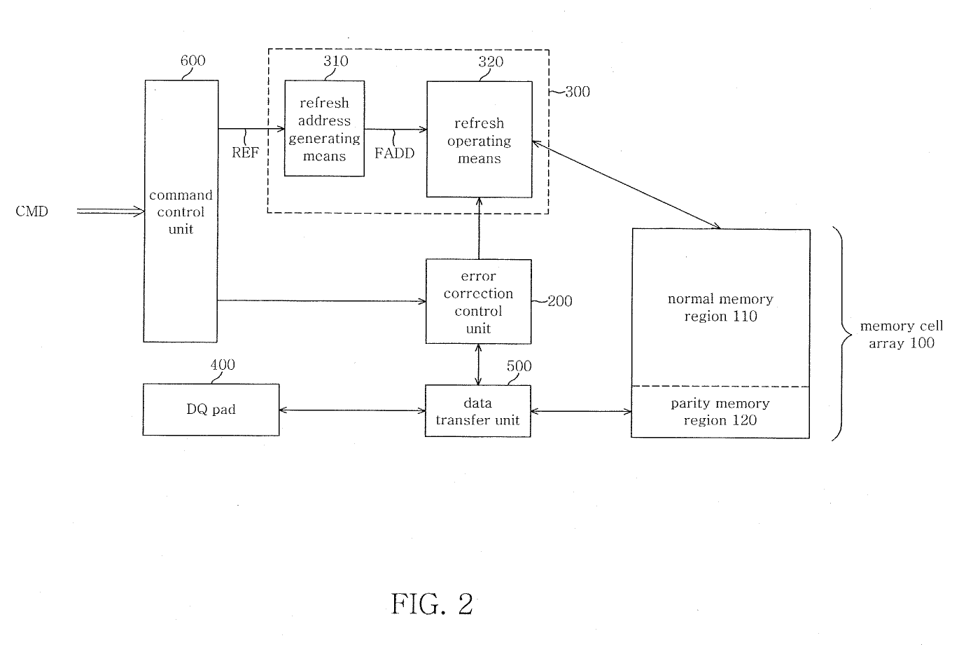

FIG. 2 is a block diagram showing a memory device useful with embodiments of the present invention. Referring to FIG. 2, the memory device includes a memory cell array 100, an error correction control unit 200, a refresh control unit 300, a DQ pad 400, a data transfer unit 500, and a command control unit 600.

The memory cell array 100 includes a normal memory region 110 and a parity memory region 120. The normal memory region 110 and the parity memory region 120 may be allocated according to a command CMD. The command CMD may include or identify region dividing information RGCON used by the memory device to divide the memory cell array 100 into the normal memory region 110 and the parity memory region 120. The command CMD may be provided to the command control unit 600 from one or more systems internal or external to the memory device.

The normal memory region 110 may store normal data NDAT that is input/output via the DQ pad 400 and the data transfer unit 500. The parity data PDAT may have a logic state associated with a bit combination of normal data NDAT.

The error correction control unit 200 is adapted to generate parity data PDAT according to at least one bit combination of normal data NDAT to be stored to the memory cell array 100. The error correction control unit 200 may generate the parity data PDAT during normal data storage operations via the data transfer unit 500. The error correction control unit 200 is adapted to detect and correct the normal data NDAT according to the parity data PDAT. The error correction control unit 200 may also detect and correct the normal data NDAT during normal data retrieval operations via the data transfer unit 500.

The refresh control unit 300 is adapted to perform refresh operations for the memory cell array 100. The refresh control unit 300 includes a refresh address generating means 310 and a refresh operating means 320. The refresh address generating means 310 generates a refresh address FADD in response to a refresh control signal REF. The refresh control signal REF may be provided by the command control unit 600 or another source internal or external to the memory device.

The refresh operating means 320 is adapted to refresh the memory cells of the memory array 100 according to the refresh address FADD. The refresh control unit 300 may cyclically perform refresh operations according to a first cycle when the normal data NDAT is stored in the parity memory region 120 of the memory cell array 100. The refresh control unit may cyclically perform refresh operations according to a second cycle when the normal data NDAT is not stored in the parity memory region 120 of the memory cell array 100. The second cycle may have a greater period or duration between refresh operations than the first cycle.

The command control unit 600 is adapted to control the error correction unit 200 and the refresh control unit 300 responsive to one or more external commands CMD. The external commands CMD may include region dividing information RGCON indicating the portions of the memory cell array 100 that correspond to the normal memory region 110 and the parity memory region 120. The memory device may divide the memory cell array 100 into the normal memory region 110 and the parity memory region 120 responsive to the region dividing information RGCON. The external command CMD may also include the information to identify whether the parity memory region 120 is capable of storing normal data NDAT.

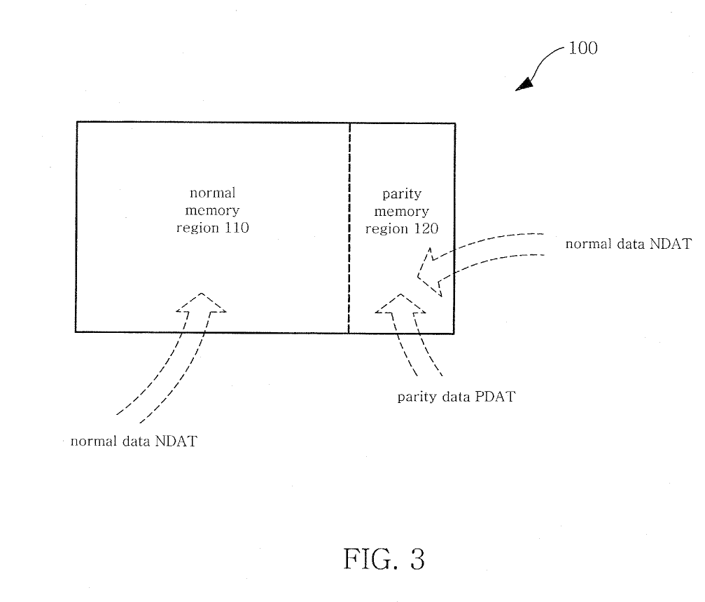

FIG. 3 is a block diagram showing example embodiments of the memory cell array 100 shown in FIG. 2. Referring to FIG. 3, the normal memory region 110 may store the normal data NDAT, and the parity memory region 120 may store the parity data PDAT. The parity memory region 120 may also store the normal data NDAT.

The memory device may refresh the memory cell array 100 according to a refresh cycle that may be dependent on the storage location of the normal data NDAT. For instance, when normal data NDAT is stored in the parity memory region 120, the memory device may execute refresh operations according to a first cycle, and when normal data NDAT is not stored in the parity memory region 120, the memory device may execute refresh operations according to a second cycle. Since the first cycle may be shorter than the second cycle, the memory device may reduce data loss associated with the first cycle and decrease current consumption associated with the second cycle. The storage of normal data NDAT in the parity memory region 120 may be monitored internally be the memory device, or by one or more external systems.

The memory device may prioritize the storage of normal data NDAT to the memory cell array 100. For instance, the parity memory region 120 may have the lowest priority for storing normal data NDAT. That is, when the normal memory region 110 is full or cannot store any more normal data NDAT, the parity memory region 120 may then be used to store normal data NDAT. This may allow the memory device to enable ECC functionality without decreasing the overall storage capacity of the memory device.

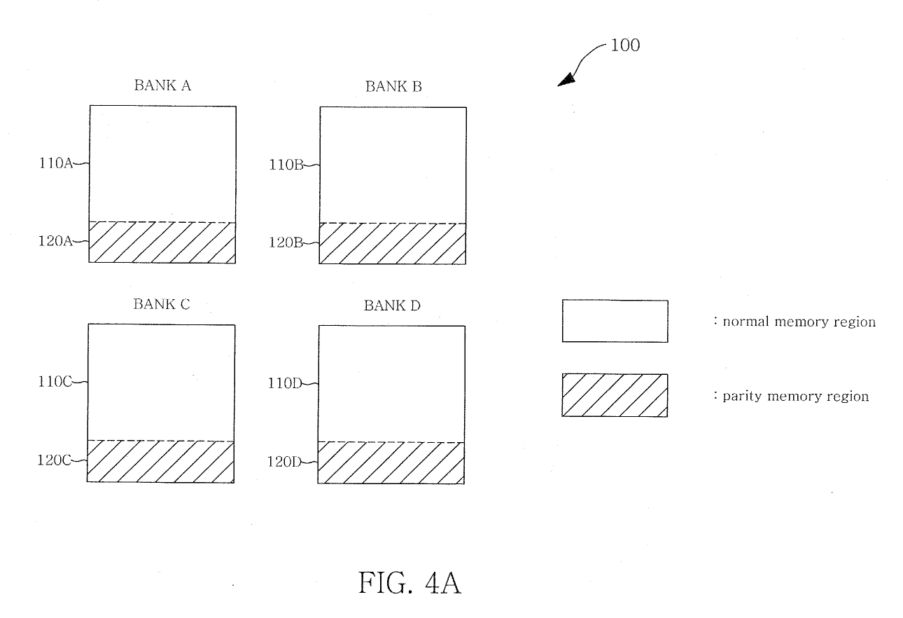

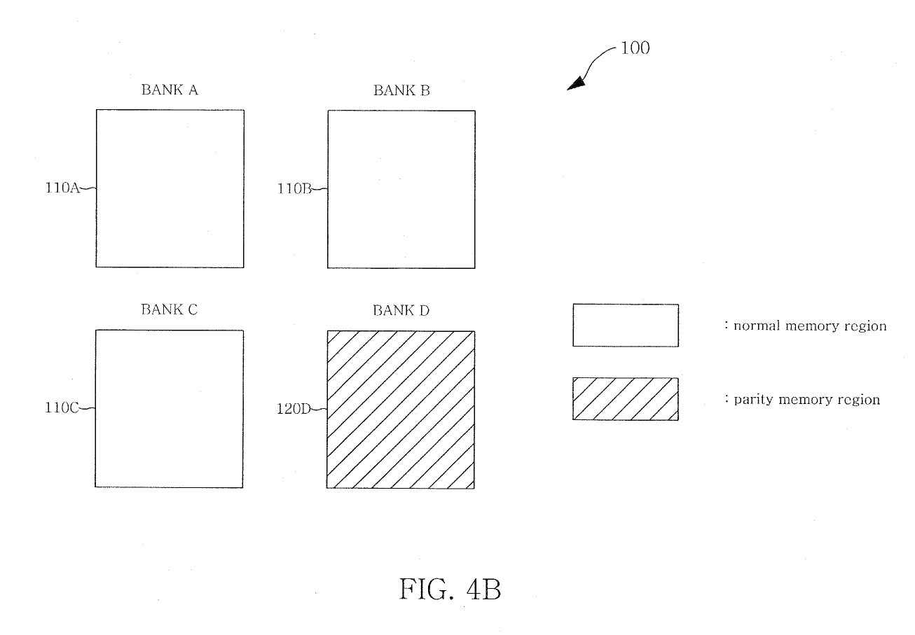

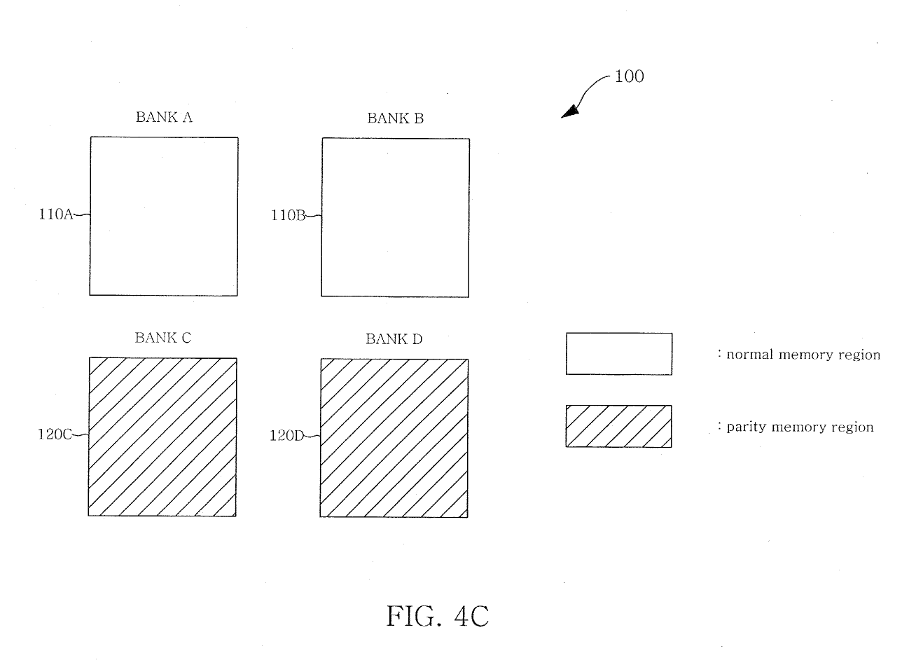

FIGS. 4A-4C are block diagrams showing other example embodiments of the memory cell array shown in FIG. 2. Referring to FIGS. 4A-4C, the memory cell array 100 includes a plurality of memory banks BANK A—BANK D. The memory cell array 100 may be divided into one or more normal memory regions 110 and one or more parity memory regions 120. For instance, in FIG. 4A, each memory bank BANK A—BANK D is divided into a parity memory region 120A-120D and a normal memory region 110A-110D. In FIG. 4B, the memory device may allocate one of the memory banks, e.g., BANK D, as the parity memory region 120D. In FIG. 4C, the memory device may allocate two or more of the memory banks, e.g., BANK C and BANK D, as the parity memory region 120C-120D.

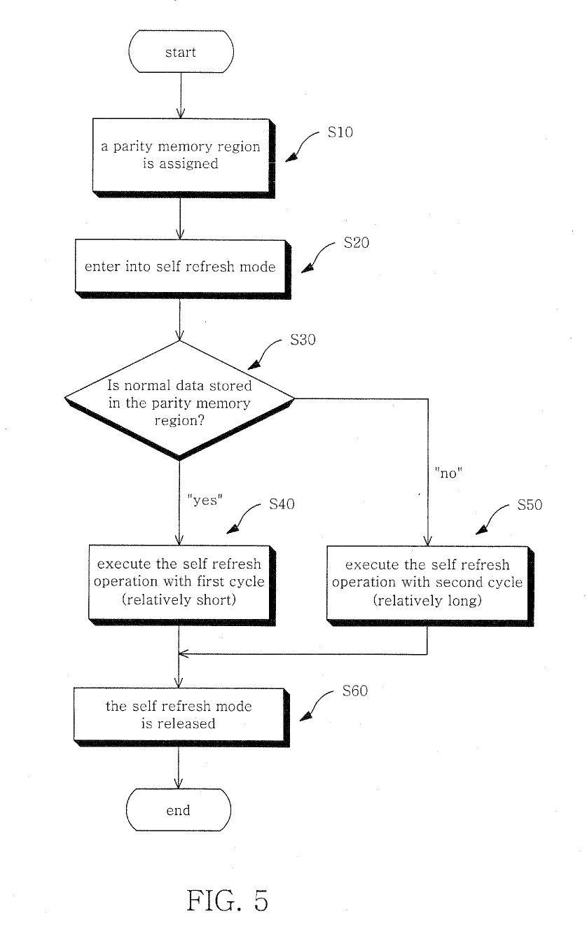

FIG. 5 is a flowchart example for the operation of the memory device shown in FIG. 2. In block S10, the normal memory region 110 and the parity memory region 120 are assigned in the memory cell array 100. The parity memory region 120 may have the lowest priority for storing normal data NDAT. The memory device may divide the memory cell array 100 into the normal memory region 110 and the parity memory region 120 responsive to one or more external commands CMD.

In block S20, the memory device enters into a self refresh operation mode. In some embodiments, the memory device may enter the self refresh mode from a standby mode or power down mode.

In block S30, the memory device determines whether normal data NDAT is stored in the parity memory region 120. When normal data NDAT is stored in the parity memory region 120, in block S40, the memory device performs one or more refresh operations on the memory cell array 100 according to a first cycle. When normal data NDAT is not stored in the parity memory region 120, in block S50, the memory device performs one or more refresh operations on the memory cell array 100 according to a second cycle. The first cycle may have a shorter period than the second cycle. In other words, the memory device may perform refresh operations with a greater frequency according to the first cycle than the second cycle.

In block S60, the memory device releases self refresh operation mode. In some embodiments the memory device may also exit from a standby mode or a power down mode. Accordingly the memory device may reduce the refresh current consumption without decreasing the storage capacity of the memory device.

The scope of the prevent invention can be extended to various data types and operation modes. In some embodiments, the normal and parity memory regions may be called as first and second memory regions, respectively, while the refresh operations associated with a first cycle may be called ‘first mode’ and the refresh operations associated with a second cycle may be called ‘second mode.’

Although embodiments of the present invention have been disclosed for illustrative purposes, those skilled in the art will appreciate that various modifications, additions and substitutions are possible, without departing from the scope and spirit of the invention as disclosed in the accompanying claims.

I claim the following:

1. A device comprising:
a memory cell array having a first region to store normal data and a second region to store both normal data and parity data associated with error correction functionality; and
a refresh control unit to perform refresh operations on the memory cell array, the refresh control unit adapted to adjust a cycle associated with the performance of the refresh operations responsive to the storage of normal data in the second region.

2. The device of claim 1 where the refresh control unit is adapted to set the cycle with a first delay between refresh operations when normal data is stored in the second region of the memory cell array.

3. The device of claim 2 where the refresh control unit is adapted to set the cycle with a second delay between refresh operations when normal data is only stored in the first region of the memory cell array.

4. The device of claim 3 where the first delay is less than the second delay.

5. The device of claim 1 including
an error correction control unit to generate the parity data according to one or more bit combinations of the normal data stored in the first region, the error correction control unit is adapted to store the parity data in the second region; and
where the memory cell array is adapted to store normal data to the second region only after the first region of the memory cell array is used to store normal data.

6. The device of claim 1 where the refresh control unit includes
a refresh address generator to generate one or more refresh addresses responsive to at least one refresh control signal; and
a refresh operator to perform refresh operations on one or more memory cells in the memory cell array according to the refresh address.

7. The device of claim 6
where the refresh operator is adapted to perform the refresh operations according to a first cycle when the normal data is stored in the second region; and
where the refresh operator is adapted to perform the refresh operations according to a second cycle when the normal data is not stored in the second region, the second cycle having a greater period than the first cycle.

8. The device of claim 1 including
a controller to assign one or more portions of the memory cell array as the second region responsive to a dividing command; and
where the memory cell array includes a plurality of memory banks, and the control unit is adapted to assign the second region to one or more of the memory banks.

9. The device of claim 8 where the control unit is adapted to assign a portion of each memory bank as the second region.

10. A method comprising:
storing normal data to a memory cell array including a normal memory region and a parity memory region, the normal memory region to store normal data and the parity memory region to store both parity data associated with error correction functionality and normal data; and
cyclically performing refresh operations on the memory cell array according to a refresh cycle, where a period of the refresh cycle varies depending on whether normal data is stored in the parity memory region.

11. The method of claim 10 includes
determining normal data is stored in the parity memory region of the memory cell array; and
increasing a frequency that the refresh operations are performed responsive to the determining.

12. The method of claim 11 includes
modifying the refresh cycle to have a shorter period responsive to the determining; and
performing refresh operations according to the refresh cycle.

13. The method of claim 10 includes
determining normal data is stored in the parity memory region of the memory cell array; and
decreasing a frequency that the refresh operations are performed responsive to the determining.

14. The method of claim 13 includes
adjusting the refresh cycle to have a shorter period responsive to the determining; and
performing the refresh operations according to a refresh cycle.

15. The method of claim 10 includes dividing a memory cell array into a normal memory region and a parity memory region responsive to one or more dividing commands.

16. A device comprising:
means for storing normal data to a memory cell array including a normal memory region and a parity memory region, the normal memory region to store normal data and the parity memory region to store both parity data associated with error correction functionality and normal data; and
means for performing refresh operations on the memory cell array according to a refresh cycle, where a period of the refresh cycle varies according to the storage of normal data in the parity memory region.

17. The device of claim 16 includes
means for determining normal data is stored in the parity memory region of the memory cell array; and
means for increasing a frequency that the refresh operations are performed responsive to the determination.

18. The device of claim 17 includes
means for modifying the refresh cycle to have a shorter period responsive to the determination; and
means for performing refresh operations according to the refresh cycle.

19. The device of claim 16 includes
means for determining normal data is stored in the parity memory region of the memory cell array; and
means for decreasing a frequency that the refresh operations are performed responsive to the determination.

20. The device of claim 19 includes
means for modifying the refresh cycle to have a shorter period responsive to the determination; and
means for performing the refresh operations according to the refresh cycle.

21. The device of claim 16 includes means for dividing a memory cell array into a normal memory region and a parity memory region responsive to one or more dividing commands.
